(19) United States
(12) Patent Application Publication
(10) Pub. No.: US 2010/0043160 A1
(43) Pub. Date: Feb. 25, 2010

(54) WAFER CLEANING ROLLER

(75) Inventor: Tzu-Shin Chen, Tainan City (TW)

Correspondence Address: NORTH AMERICA INTELLECTUAL PROPERTY CORPORATION, P.O. BOX 506, MERRIFIELD, VA, 22116, US

(73) Assignee: UNITED MICROELECTRONICS CORP., Hsinchu (TW)

(21) Appl. No.: 12/195,021

(22) Filed: Aug. 20, 2008

(51) Int. Cl. H01L 21/00

(52) U.S. Cl. 15/102

(57) ABSTRACT

A wafer cleaning roller including a tube body and a plurality of first protrusions is provided. The tube body has a longitudinal direction. The first protrusions are disposed on the outside surface of the tube body. Each of the first protrusions is shaped as a stripe having a first extension direction. The included angle between the first extension direction and the longitudinal direction is an oblique angle.

### BACKGROUND OF THE INVENTION

1. Field of Invention

The present invention relates to a wafer cleaning device, and more generally relates to a wafer cleaning roller.

2. Description of Related Art

In an IC device fabrication process, the most frequently applied step is a wafer cleaning step, which is for removing the pollutants including organic compounds, metal impurities or particles adhered to the wafer surface. These pollutants have a great impact to the subsequent processes of the product. For example, metal impurities result in a leakage current of the p-n junction, a shorter lifetime of certain carriers and a lower breakdown voltage of the gate oxide layer. Particles may cause errors in pattern transferring of a lithography process and even a short in the circuit structure. Therefore, it is necessary to effectively remove organic compounds, metal impurities or particles adhered to the wafer surface in the wafer cleaning step.

FIG. 1 schematically illustrates a diagram of a conventional wafer cleaning device. FIG. 2 schematically illustrates a front view of another conventional wafer cleaning roller.

Referring to FIG. 1, a wafer cleaning device includes pulleys 102, a roller 104 and a rolling shaft 106, wherein the roller 104 covers the rolling shaft 106. The roller 104 includes a tube body 108 and protrusions 110 disposed on the roller body 108. When a cleaning step is processed, a wafer 112 is clipped by the pulleys 102, and the wafer 112 is rotated along the direction 114. On the other side, a cleaning solution 116 is coated on the surface of the wafer 112. Meanwhile, the protrusions 110 of the roller 106 are in contact with the surface of the wafer 112, and the rolling shaft 106 and the roller 104 are rotated along the direction 120. Thus, the pollutants adhered to the surface of the wafer 112 are removed by the protrusions 110 of the roller 104.

However, in the wafer cleaning device 100, the protrusions 110 are shaped as circles, so that the edge of the wafer 112 cannot be cleaned completely, and the drainage property is not good enough.

Referring to FIG. 2, another conventional wafer cleaning roller 200 is provided. The protrusions 204 of the tube body 202 are shaped as stripes. Although the protrusions 204 shaped as stripes can slightly improve the problem of incomplete cleaning around the wafer edge, the performance is not significant and the problem of bad drainage property is still present.

### SUMMARY OF THE INVENTION

Accordingly, the present invention provides a wafer cleaning roller to effectively improve the wafer cleaning efficiency and the drainage property.

The present invention provides a wafer cleaning roller including a tube body and a plurality of first protrusions. The tube body has a longitudinal direction. The first protrusions are disposed on the outside surface of the tube body. Each of the first protrusions is shaped as a stripe having a first extension direction. The included angle between the first extension direction and the longitudinal direction is an oblique angle.

According to an embodiment of the present invention, a material of the wafer cleaning roller includes an elastic material, for example.

According to an embodiment of the present invention, the elastic material includes sponge, for example.

According to an embodiment of the present invention, the oblique angle includes an obtuse angle or an acute angle, for example.

According to an embodiment of the present invention, the oblique angles are the same as each other.

According to an embodiment of the present invention, the oblique angles include at least two angles.

According to an embodiment of the present invention, a sidewall of each of the first protrusions is perpendicular to a surface of the tube body.

According to an embodiment of the present invention, a sidewall of each of the first protrusions has an inclined surface, for example.

According to an embodiment of the present invention, the wafer cleaning roller further includes a plurality of second protrusions, disposed on the outside surface of the tube body.

According to an embodiment of the present invention, the second protrusions have the same shapes, for example.

According to an embodiment of the present invention, the second protrusions have different shapes, for example.

According to an embodiment of the present invention, shapes of the second protrusions include circles, ellipses, polygons or irregular shapes, for example.

According to an embodiment of the present invention, each of the second protrusions is shaped as a stripe having a second extension direction.

According to an embodiment of the present invention, the second extension direction is parallel to the longitudinal direction, for example.

According to an embodiment of the present invention, the second extension direction is perpendicular to the longitudinal direction, for example.

According to an embodiment of the present invention, a sidewall of each of the second protrusions includes an inclined surface, for example.

In the present invention, each of the included angles between each of the first extension directions of the first protrusions and the longitudinal direction of the tube body is an oblique angle, so that the wafer cleaning efficiency and the drainage property are significantly improved.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 schematically illustrates a diagram of a conventional wafer cleaning device.

FIG. 2 schematically illustrates a front view of another conventional wafer cleaning roller.

FIG. 3 schematically illustrates a wafer cleaning roller according to the first embodiment of the present invention.

FIG. 4 schematically illustrates a front view of a wafer cleaning roller according to the first embodiment of the present invention.

FIG. 5 schematically illustrates a front view of a wafer cleaning roller according to the second embodiment of the present invention.

FIG. 6 schematically illustrates a front view of a wafer cleaning roller according to the third embodiment of the present invention.

FIG. 7 schematically illustrates a front view of a wafer cleaning roller according to the fourth embodiment of the present invention.

FIG. 8 schematically illustrates a cross-sectional view taken along the line A-A′ of the third embodiment.

FIG. 9 schematically illustrates a cross-sectional view of a wafer cleaning roller taken along the line A-A′ of the third embodiment according to the fifth embodiment of the present invention.

FIG. 10 schematically illustrates a cross-sectional view of a wafer cleaning roller taken along the line A-A′ of the third embodiment according to the sixth embodiment of the present invention.

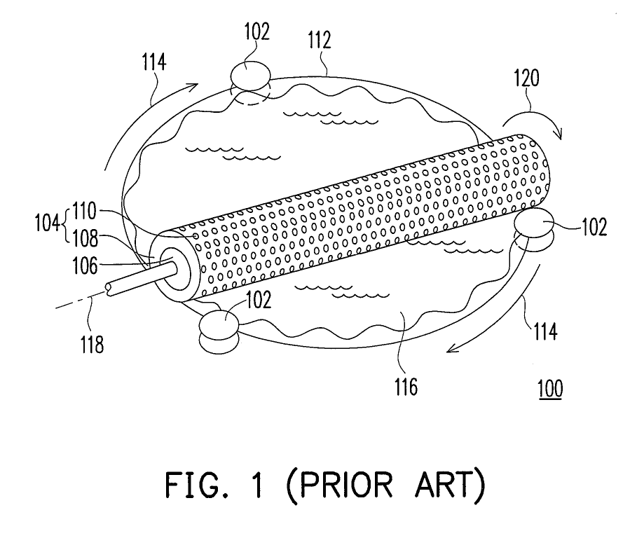

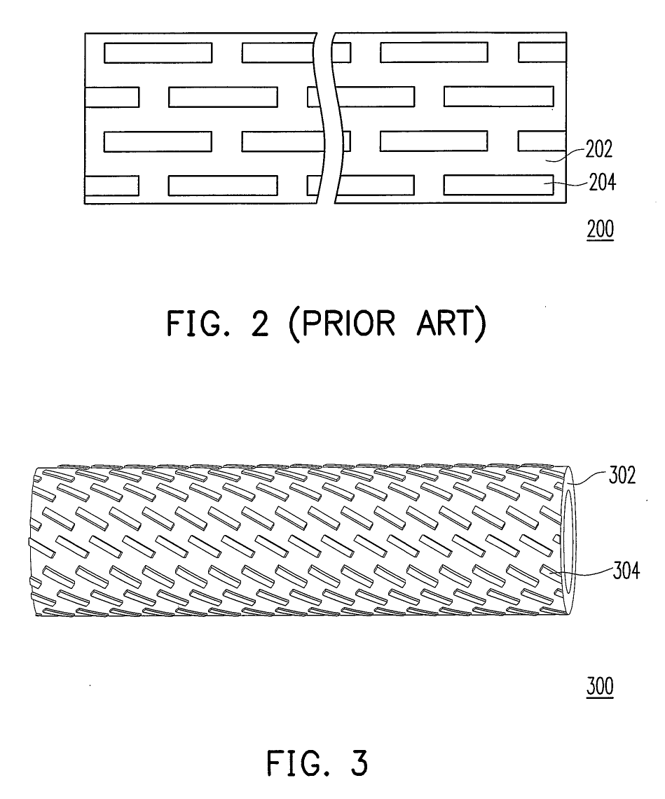

### DESCRIPTION OF EMBODIMENTS

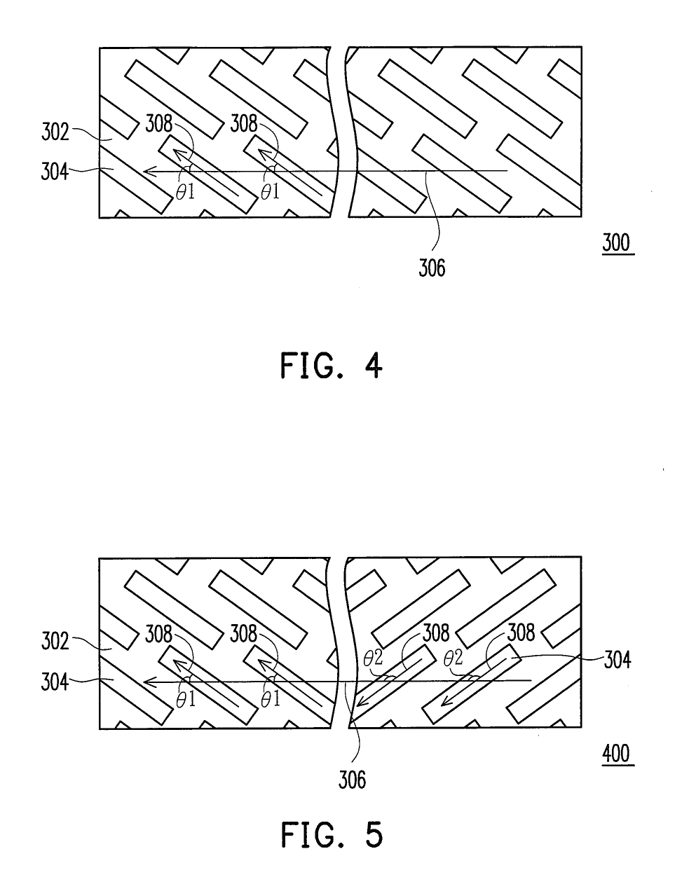

FIG. 3 schematically illustrates a wafer cleaning roller according to the first embodiment of the present invention. FIG. 4 schematically illustrates a front view of a wafer cleaning roller according to the first embodiment of the present invention.

Referring to FIGS. 3 and 4, a wafer cleaning roller 300 includes a tube body 302 and protrusions 304. The wafer cleaning roller 300 covers the rolling shaft of the wafer cleaning device. The wafer cleaning roller 300 is applicable for cleaning the wafer surface with the cleaning solution, so as to remove the pollutants of the wafer surface. The material of the wafer cleaning roller 300 may be an elastic material such as sponge for preventing the wafer surface from being damaged during the cleaning process.

The tube body 302 has a longitudinal direction 306. The protrusions 304 are disposed on the outside surface of the tube body 302. The protrusions 304 are shaped as stripes having extension directions 308. Each of the included angles between each of the extension directions 308 and the longitudinal direction 306 is an oblique angle θ1. These oblique angles θ1 can be obtuse angles or acute angles. This embodiment is illustrated by exemplifying that these oblique angles θ1 are acute angles.

This embodiment in which these oblique angles θ1 are the same as each other is provided for illustration purposes, and is not to be construed as limiting the present invention. In another embodiment, these oblique angles θ1 can be different from one another. It is appreciated by persons skilled in the art that the oblique angles θ1 can be adjusted upon the design requirement.

In this embodiment, each of the included angles between each of the extension directions 308 of the protrusions 304 and the longitudinal direction 306 of the tube body 302 is an oblique angle θ1, so that the wafer edge can be cleaned effectively with the wafer cleaning roller 300, and the wafer cleaning performance is significantly improved.

Further, each of the included angles between each of the extension directions 308 and the longitudinal direction 306 is an oblique angle θ1, so that the flowing path is formed between the stripe-shaped protrusions 304, the cleaning solution can flow out of the wafer along the flowing path, and thus a better drainage property is obtained.

FIG. 5 schematically illustrates a front view of a wafer cleaning roller according to the second embodiment of the present invention. The same reference numbers for the same components are used in FIGS. 4 and 5, and thus the details are not iterated.

Referring to FIGS. 4 and 5, the difference between the wafer cleaning roller 400 of the second embodiment and the wafer cleaning roller 300 of the first embodiment is described in the following. In the first embodiment, each of the included angles between each of the extension directions 308 of the protrusions 304 and the longitudinal direction 306 of the tube body 302 is the same; that is, the included angles are respectively an oblique angle θ1. However, in the second embodiment, each of the included angles between each of the extension directions 308 of the protrusions 304 and the longitudinal direction 306 of the tube body 302 is not totally the same; that is, the included angles include oblique angles θ1 and θ2. The oblique angles θ1 may be acute angles and the oblique angles θ2 may be obtuse angles. This embodiment is illustrated, but not limited to, by exemplifying two kinds of the oblique angles θ1 and θ2. It is appreciated by persons skilled in the art that more than three kinds of the oblique angles can be applied, and the oblique angles can be adjusted upon the design requirement. Further, the functions and materials of similar components in the first and second embodiments are substantially the same, so that the details are not iterated.

Similarly, in the second embodiment, each of the included angles between each of the extension directions 308 of the protrusions 304 and the longitudinal direction 306 of the tube body 302 is an oblique angle, and these oblique angles include oblique angles θ1 and θ2, so that the wafer cleaning efficiency and the drainage property are significantly improved.

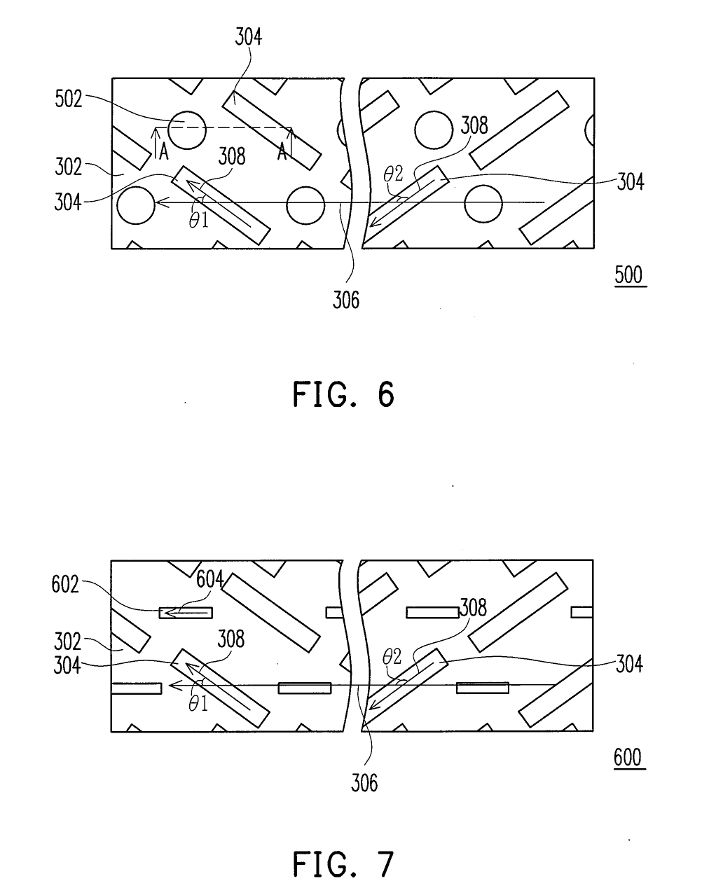

FIG. 6 schematically illustrates a front view of a wafer cleaning roller according to the third embodiment of the present invention. The same reference numbers for the same components are used in FIGS. 5 and 6, and thus the details are not iterated.

Referring to FIGS. 5 and 6, the difference between the wafer cleaning roller 500 of the third embodiment and the wafer cleaning roller 400 of the second embodiment is described in the following. In the third embodiment, the wafer cleaning roller 500 further includes protrusions 502 except the protrusions 304. The protrusions 502 are disposed on the outside surface of the body tube 302. In this embodiment, the protrusions 502 are shaped as circles, for example. In another embodiment, the shapes of the protrusions 502 include ellipses, polygons or irregular shapes, for example. It is appreciated by persons skilled in the art that the shapes of the protrusions 502 can be adjusted upon the design requirement. Further, the functions and materials of similar components in the second and third embodiments are substantially the same, so that the details are not iterated.

Similarly, in the third embodiment, each of the included angles between each of the extension directions 308 of the protrusions 304 and the longitudinal direction 306 of the tube body 302 is an oblique angle, and these oblique angles include oblique angles θ1 and θ2, so that the wafer cleaning efficiency and the drainage property are significantly improved.

FIG. 7 schematically illustrates a front view of a wafer cleaning roller according to the fourth embodiment of the present invention. The same reference numbers for the same components are used in FIGS. 7 and 5, and thus the details are not iterated.

Referring to FIGS. 7 and 5, the difference between the wafer cleaning roller 600 of the fourth embodiment and the wafer cleaning roller 400 of the second embodiment is described in the following. In the fourth embodiment, the wafer cleaning roller 600 further includes protrusions 602 except the protrusions 304. The protrusions 602 are disposed on the outside surface of the body tube 302. The protrusions 602 are shaped as stripes having extension directions 604. In this embodiment, the extension directions 604 are parallel to the longitudinal direction 306. In another embodiment, the extension directions 604 are respectively parallel to or perpendicular to the longitudinal direction 306, which can be adjusted upon the design requirement by persons skilled in the art. Further, the functions and materials of similar components in the second and fourth embodiments are substantially the same, so that the details are not iterated.

Similarly, in the fourth embodiment, each of the included angles between each of the extension directions 308 of the protrusions 304 and the longitudinal direction 306 of the tube body 302 is an oblique angle, and these oblique angles include oblique angles θ1 and θ2, so that the wafer cleaning efficiency and the drainage property are significantly improved.

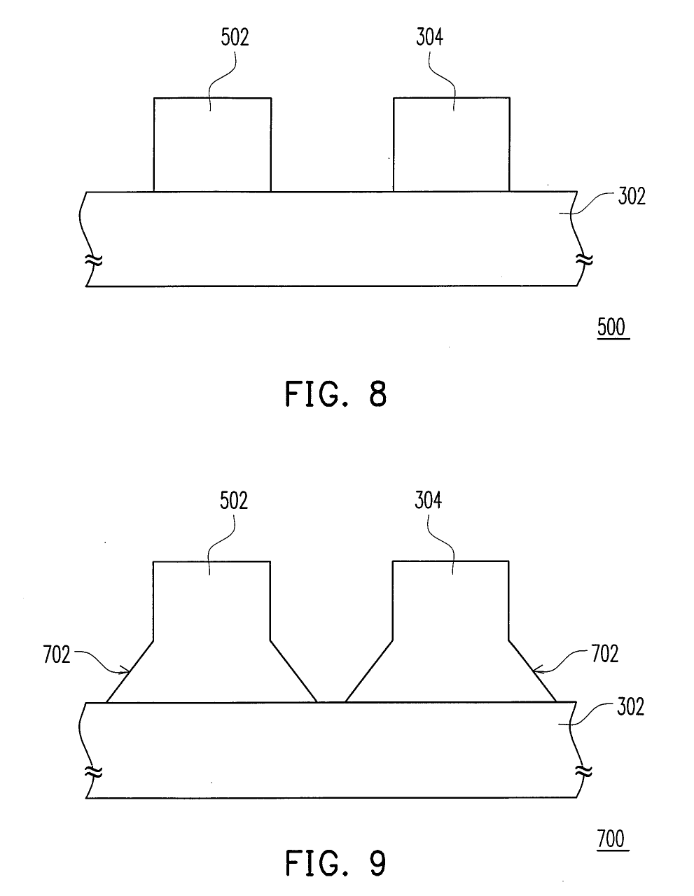

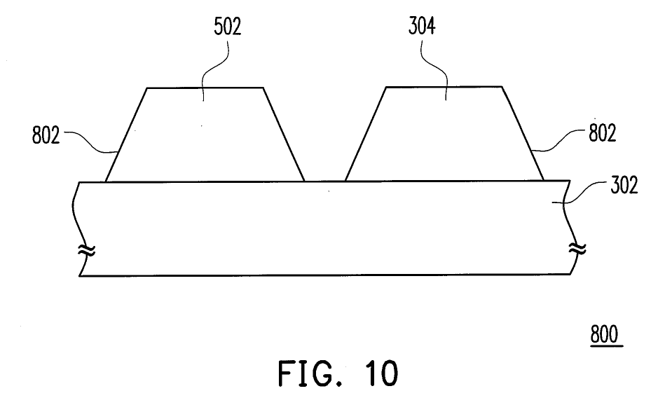

FIG. 8 schematically illustrates a cross-sectional view taken along the line A-A′ of FIG. 6. FIGS. 9 and 10 respectively illustrate cross-sectional views of a wafer cleaning roller taken along the line A-A′ of the third embodiment according to the fifth and sixth embodiments of the present invention. The same reference numbers for the same components are used in FIGS. 8 to 10, and thus the details are not iterated.

Referring to FIG. 8, the sidewalls of the protrusions 304 and 502 of the wafer cleaning roller 500 are, for example but not limited to, perpendicular to the surface of the tube body 302. Referring to FIG. 9, in the wafer cleaning roller 700, a portion of the sidewalls of the protrusions 304 and a portion of the sidewalls of the protrusions 502 are inclined surfaces 702, so that the bottom support of the protrusions 304 and 502 is enhanced, and the damage or coming off of the protrusions can be avoided during the cleaning process. Referring to FIG. 10, in the wafer cleaning roller 800, the sidewalls of the protrusions 304 and 502 are inclined surfaces 802, so that the bottom support of the protrusions 304 and 502 is enhanced, and the damage or coming off of the protrusions can be avoided during the cleaning process.

In summary, the above-mentioned embodiments at least have the following advantages:

1. The wafer cleaning roller of the present invention can significantly improve the wafer cleaning efficiency.

2. The wafer cleaning roller of the present invention has a better drainage property.

3. When the sidewalls of the protrusions of the above-mentioned embodiments have inclined surfaces, the damage or coming off of the protrusions can be avoided during the cleaning process.

This invention has been disclosed above in the preferred embodiments, but is not limited to those. It is known to persons skilled in the art that some modifications and innovations may be made without departing from the spirit and scope of this invention. Hence, the scope of this invention should be defined by the following claims.

1. A wafer cleaning roller, comprising:
a tube body, having a longitudinal direction; and
a plurality of first protrusions, disposed on an outside surface of the tube body,
wherein each of the first protrusions is shaped as a stripe having a first extension direction, and an included angle between the first extension direction and the longitudinal direction is an oblique angle.

2. The wafer cleaning roller of claim 1, wherein a material of the wafer cleaning roller comprises an elastic material.

3. The wafer cleaning roller of claim 1, wherein the elastic material comprises sponge.

4. The wafer cleaning roller of claim 1, the oblique angle comprises an obtuse angle or an acute angle.

5. The wafer cleaning roller of claim 1, wherein the oblique angles are the same as each other.

6. The wafer cleaning roller of claim 1, wherein the oblique angles include at least two angles.

7. The wafer cleaning roller of claim 1, wherein a sidewall of each of the first protrusions is perpendicular to a surface of the tube body.

8. The wafer cleaning roller of claim 1, wherein a sidewall of each of the first protrusions comprises an inclined surface.

9. The wafer cleaning roller of claim 1, further comprising a plurality of second protrusions, disposed on the outside surface of the tube body.

10. The wafer cleaning roller of claim 9, wherein the second protrusions have the same shapes.

11. The wafer cleaning roller of claim 9, wherein the second protrusions have different shapes.

12. The wafer cleaning roller of claim 9, wherein shapes of the second protrusions comprise circles, ellipses, polygons or irregular shapes.

13. The wafer cleaning roller of claim 9, wherein each of the second protrusions is shaped as a stripe having a second extension direction.

14. The wafer cleaning roller of claim 13, wherein the second extension direction is parallel to the longitudinal direction.

15. The wafer cleaning roller of claim 13, wherein the second extension direction is perpendicular to the longitudinal direction.

16. The wafer cleaning roller of claim 9, wherein a sidewall of each of the second protrusions comprises an inclined surface.
